(19) United States
(12) Patent Application Publication
(10) Pub. No.: US 2025/0051923 A1
(43) Pub. Date: Feb. 13, 2025

(54) METHODS OF DEPOSITING MATERIALS ONTO 2-DIMENSIONAL LAYERED MATERIALS

(71) Applicant: OXFORD INSTRUMENTS NANOTECHNOLOGY TOOLS LIMITED, Abingdon Oxon (GB)

(72) Inventors: Sarah RIAZIMEHR, Abingdon Oxfordshire (GB); Harm KNOOPS, Abingdon Oxfordshire (GB); Ravi SUNDARAM, Abingdon Oxfordshire (GB)

(21) Appl. No.: 18/719,983

(22) PCT Filed: Dec. 14, 2022
(86) PCT No.: PCT/GB2022/053231

§ 371 Date: Jun. 14, 2024

(30) Foreign Application Priority Data
Dec. 15, 2021 (GB) 2118203.5

(51) Int. Cl. C23C 16/505; C23C 16/30; C23C 16/455; C23C 16/515

(52) U.S. Cl. CPC C23C 16/505; C23C 16/303; C23C 16/45536; C23C 16/515

(57) ABSTRACT

A method for plasma deposition of materials onto a 2-dimensional layer of a first substrate, the method comprising: depositing a protective layer directly onto the 2-dimensional layer in a pulsed plasma deposition process; and depositing a second layer onto the protective layer in a second plasma deposition process.

The present invention relates to methods of depositing materials onto 2-dimensional layered materials.

### BACKGROUND

2-dimensional materials such as graphene have been demonstrated in a range of proof-of-concept devices to allow for high performance. These materials are ideally combined with a range of other materials to provide functional devices. However, the surfaces of 2-dimensional materials such as graphene are relatively inert which makes it challenging to deposit other materials, such as dielectrics, onto the surface of these 2-dimensional materials using thermal and plasma based vapour deposition processes, such as atomic layer deposition (ALD). At the same time, the surfaces of 2-dimensional materials are sensitive to damage by, for instance, plasma radicals and ions produced in plasma processes.

Attempts have been made at using atomic layer deposition to deposit dielectric layers onto 2-dimensional materials. For example, atomic layer deposition of Al₂O₃ onto graphene has been attempted by seeding the surface of the graphene by evaporating Al onto its surface followed by oxidizing the Al to produce Al₂O₃. Performing thermal atomic layer deposition using extended dosing has also been attempted. However, both these methods result in low-quality dielectric layers.

A high-quality interlayer that can be used to protect the graphene when depositing Al₂O₃ is hBN (hexagonal boron nitride). This material is also inert, but it is more resistant to damage than graphene so can be used to protect the graphene during plasma enhanced atomic layer deposition (PEALD). However, depositing hBN on a graphene surface adds an additional 2-dimensional material growth and transfer step in the process flow which is challenging and difficult to scale.

The interest in 2-dimensional materials has increased in recent years, as it promises a significant performance increase for telecommunication and data communication components by enabling ultra wide bandwidths and low power consumption. In addition, the unprecedented surface area to volume ratios of 2-dimensional materials coupled with superior electronic properties make 2-dimensional materials attractive for a wide range of sensors. Such applications in data communication and sensors require integration with high quality dielectric layers, in particular, on graphene and other 2-dimensional materials.

Improved methods of depositing materials onto 2-dimensional layers are, therefore, required.

### SUMMARY

According to a first aspect of the invention, a method for plasma deposition of materials onto a 2-dimensional layer of a first substrate is provided, the method comprising: depositing a protective layer directly onto the 2-dimensional layer in a pulsed plasma deposition process; and depositing a second layer onto the protective layer in a second plasma deposition process.

The first aspect of the invention allows for materials to be deposited onto a 2-dimensional layer, by which we mean a layer of a 2-dimensional material such as graphene, without damaging the 2-dimensional layer and whilst ensuring the deposited materials are high quality, which is to say that the materials are deposited in high density closed layers, with clean interfaces between layers, with low physical and electronic defects, and, in the case of dielectrics, with high break down voltages, high dielectric constants (considered to be a dielectric constant of 3 or more), and low leakage currents. The properties of 2-dimensional materials such as graphene mean that their surfaces have a low density of nucleation sites, leading to delays in the nucleation of deposited materials, which in turn means that the chemical processes used to deposit these materials must be carried out using a sufficient exposure of reactive species (such as plasma species). However, 2-dimensional materials are also highly sensitive to damage, which means that extended exposure to reactive species can lead to excessive damage of 2-dimensional materials.

This problem is addressed by the first aspect of the invention by using a pulsed plasma deposition process to first deposit a protective layer onto the 2-dimensional layer. A pulsed plasma deposition process is a plasma deposition process in which one or both of the precursor gas and the plasma are pulsed, which is to say that the precursor gas and/or the plasma are provided cyclically. In the case of the precursor gas this means providing the precursor gas over a first time interval and then purging the deposition chamber (also referred to herein as a processing chamber) for a second time interval and repeating this cycle over the course of the deposition process. For the avoidance of doubt, the precursor gas is provided absent a plasma (such as would be the case in the first stage of a deposition cycle during plasma enhanced atomic layer deposition), while the gas (or gases) provided in the presence of a plasma to generate reactive species such as radicals and ions is (or are) referred to as a plasma gas (or plasma gases). The plasma is pulsed either by pulsing the plasma gas, i.e. by providing the plasma gas over a first time interval and then purging the deposition chamber for a second time interval and repeating this cycle over the course of the deposition process, or by providing the power to the plasma in pulses.

Using a pulsed plasma deposition process ensures that the surface of the 2-dimensional layer is sufficiently exposed to the reactive species for deposition to occur, whilst also minimizing exposure of the 2-dimensional layer to reactive species which can damage the 2-dimensional layer, such as high energy ions or excessive levels of radicals.

The use of a pulsed plasma deposition process is, therefore, highly effective at reducing damage caused by reactive species. However, the 2-dimensional layer can still be damaged by reactive radicals used in the pulsed plasma deposition process depending on the type of radicals and/or on how high a dose of radicals is provided.

A particular example of radicals damaging a 2-dimensional layer occurs when depositing Al₂O₃ onto graphene. It has been found that even when damage from ions in the plasma is minimized, the oxygen radicals in the plasma gas used to deposit the Al₂O₃ are highly reactive with the surface of the graphene leading to damage. This also occurs with other combinations of materials and avoiding damage caused by radicals in a plasma gas is, therefore, an important problem to be addressed.

In the first aspect of the invention this is achieved by providing a protective layer. The protective layer does not exhibit the same sensitivity to damage as the 2-dimensional layer, meaning that deposition processes which would damage the 2-dimensional layer can be used to deposit the second layer without damaging either the protective layer or the 2-dimensional layer.

The first aspect of the invention therefore allows for high quality layers of materials to be deposited onto a 2-dimensional layer without damaging said 2-dimensional layer.

The first aspect of the invention contrasts with the use of an hBN protective layer, in particular, as it does not require separate, ex situ, material growth and transfer steps. Instead, the deposition of the protective layer occurs in situ and therefore allows for the integration of graphene into semiconductor fabrication processes without additional steps such as an ex situ seed layer or hBN deposition, which cause major scaling and infrastructure challenges and, as a result, device cost issues.

In the description above, and throughout this specification, the words “on” and “onto” should not, when used in the context of the deposition or provision of one layer material on or onto another layer of material, be construed as excluding the possibility of depositing or providing one or more intermediate layers. In such cases where there are no intermediate layers between two layers of material, the expressions “directly on” or “directly onto” will be used. For example, in the first aspect of the invention, the protective layer is deposited directly onto the 2-dimensional layer, meaning that there are no intermediate layers. There could, however, be one or more intermediate layers provided between the protective layer and the second layer.

For the avoidance of doubt, the first substrate may comprise further layers in addition to the 2-dimensional layer or may, alternatively, comprise only the 2-dimensional layer.

As will be apparent from the above, the first aspect of the invention is particularly suited to depositing materials onto graphene owing to the difficulties in avoiding damage to the graphene layer. The low density of nucleation sites in the graphene surface, in particular, makes the deposition of materials challenging, whilst the sensitivity of graphene to damage means that this cannot be overcome by simply using more intense deposition processes (i.e. deposition processes involving extended exposure to reactive species).

Other materials which can be used to form the 2-dimensional layer and which benefit from the first aspect of the invention are Molybdenum DiSulphide (MoS₂), Tungsten Disulphide (WS₂), Molybdenum or Tungsten Selenides, Borophene, and Silicene.

To this end, the composition of the protective layer is chosen so as to allow for a use of a plasma gas in which the radicals do not damage the underlying 2-dimensional layer. Particular examples include metal or semiconductor nitrides, metal or semiconductor carbides, and metal or semiconductor carbonitrides.

For the avoidance of doubt, the expression “metal or semiconductor nitride” means a nitride of a metallic element or a nitride of a semiconductor element. The metal or semiconductor nitride compound itself need not be a metal or a semiconductor but could, for example, be a dielectric. Similarly, the expression “metal or semiconductor carbide” means a carbide of a metallic element or a carbide of a semiconductor element, and the metal or semiconductor carbide compound itself need not be a metal or a semiconductor but could, for example, be a dielectric, while the expression “metal or semiconductor carbonitride” means a carbonitride of a metallic element or a carbonitride of a semiconductor element, and the metal or semiconductor carbonitride compound itself need not be a metal or a semiconductor but could, for example, be a dielectric.

For example, AlN is especially suitable for use as a protective layer for graphene as the nitrogen radicals in the plasma gas do not damage the graphene when supplied in a sufficiently low dose, in contrast to the oxygen radicals in the plasma gas used when depositing Al₂O₃. The second layer may contain oxygen because the first layer shields the sensitive two dimensional layer from oxidation during processing, and as such the use of AlN as a protective layer allows for the deposition of a Al₂O₃ layer onto graphene.

Other suitable materials for use as protective layers include Silicon Nitride, Titanium Nitride, Silicon Carbide, Titanium Carbonitride, Silicon Carbonitride, and Titanium Aluminium Nitride.

The protective layer preferably comprises a dielectric. As will be apparent from the description above, in many implementations of the invention the second layer comprises a dielectric. In such cases, it is advantageous for the protective layer to also comprise a dielectric since the protective layer forms the first interface with the 2-dimensional layer. A dielectric protective layer can also be advantageous when the second layer (or any intermediate layers between the protective layer and the second layer) are metallic as the protective layer could then be configured to act as a dielectric tunnel barrier. For example, a layer of titanium nitride (TIN) could be provided directly on a protective layer formed from AlN. In other implementations, however, the protective layer might also be formed from a metal, such as TiN, or a semiconductor.

It is especially advantageous if one or both of the protective layer and the second layer comprise a high-k dielectric, which is to say a dielectric with a dielectric constant greater than or equal to 3.

In order to minimise damage to the 2-dimensional layer and to maximise the quality of the protective layer, the pulsed plasma deposition process advantageously comprises a plasma enhanced atomic layer deposition process.

A plasma enhanced atomic layer deposition process is an example of a pulsed plasma deposition process, being a cyclic deposition process carried out under near vacuum conditions such that the maximum pressure during processing is around 1 mbar. A precursor (typically also referred to as a precursor vapour, which could be a gas or, in some instances, could comprise a highly diffuse evaporated liquid under low pressure) is first provided in the deposition chamber along with a substrate onto which a material is to be deposited. The precursor reacts with the surface of the substrate in a self-limiting reaction, which is to say the reaction ends once all nucleation sites on the surface of the substrate have reacted with the precursor, resulting in a solid thin film (which is typically no more than one atom thick) of adsorbed species on the surface of the substrate. Any excess precursor is then purged from the deposition chamber (typically by providing a purge gas such as argon), after which a plasma is used to provide radicals which react with the adsorbed species on the surface of the substrate and provide new reactive sites for the precursor to adsorb to in the subsequent step and to leave a layer of deposited material. Any formed reaction products are then purged from the deposition chamber and the process is repeated as many times as necessary to leave the desired number of layers of deposited material.

As the plasma is only provided for a small proportion of each deposition cycle during plasma enhanced atomic layer deposition, the amount of time the substrate is exposed to ions and radicals in the plasma can be reduced. This means that plasma enhanced atomic layer deposition allows easy control of the resulting exposure of plasma species on the 2-dimensional layer of the first substrate when used to deposit the protective layer, especially when the composition of the protective layer is chosen in such a way that the radicals formed in the plasma used to deposit the protective layer do not damage the 2-dimensional layer of the first substrate. For example, the plasma used to deposit AlN on a graphene layer comprises reactive species such as nitrogen radicals, which do not damage the surface of the graphene layer when supplied in a sufficiently low dose. Low energy plasma enhanced atomic layer deposition is, therefore, particularly suited to depositing the protective layer directly onto the 2-dimensional layer of the first substrate.

An alternative to plasma enhanced atomic layer deposition is pulsed plasma enhanced chemical vapour deposition. In plasma enhanced chemical vapour deposition, a number of reactive species are present in a plasma and these then react with the surface of a substrate to form a layer of deposited material. Typically, this means that ions and (potentially damaging) radicals are present throughout the deposition process, which can lead to damage to substrates comprising sensitive materials, such as the 2-dimensional layer of the first substrate in the first aspect of the invention. This can be mitigated by pulsing the power to the plasma source and/or by pulsing the supply of plasma gases to the deposition chamber, thereby reducing the exposure of the substrate to ions and/or radicals. Nevertheless, plasma enhanced atomic layer deposition is preferable to pulsed plasma enhanced chemical vapour deposition as plasma enhanced atomic layer deposition typically results in less damage to the substrate and allows more precise layer thickness & layer/film quality control. This is due to the plasma only being provided for a small proportion of a deposition cycle during plasma enhanced atomic layer deposition. Even when the power to the plasma is pulsed during a pulsed plasma enhanced chemical vapour deposition process, the plasma is typically present for a greater amount of time than in a comparable plasma enhanced atomic layer deposition process, leading to greater damage to the substrate from ions and/or radicals. Plasma enhanced atomic layer deposition also leads to greater uniformity and density of deposited layers owing to the deposited materials being deposited in one atom thick layers, whereas this precise control over the deposition of materials is not possible during plasma enhanced chemical vapour deposition.

In order to further reduce damage to the 2-dimensional layer, the plasma used in the pulsed plasma deposition process is preferably low energy, which is to say the power supplied to the plasma source is 100 W or less, or more preferably is 25 W or less. In the specific case of a low energy PEALD process, “a low energy PEALD process” may also be defined as a PEALD process in which the ion flux to the wafer during any plasma step is below 0.2 mA per square centimeter, and the ion energy is below 30 eV. A suitable plasma source has been described in GB2577697. The use of a low energy plasma results in the creation of fewer ions and means that the ions reaching the substrate have less energy, thereby reducing the damage caused to the 2-dimensional layer.

The deposition of a protective layer means that any conventional deposition process could be used to deposit the second layer, including non-pulsed plasma deposition processes such as non-pulsed plasma enhanced chemical vapour deposition. Nevertheless, it is preferable for the second plasma deposition process to comprise a pulsed plasma deposition process, such as plasma enhanced atomic layer deposition or pulsed plasma enhanced chemical vapour deposition.

Although the protective layer is less sensitive to damage than the 2-dimensional layer, it is nevertheless desirable to reduce any potential for damage to the protective layer (and possibly also to the 2-dimensional layer underneath) to occur. It is also preferable for the second plasma deposition process to be of the same type as the pulsed plasma deposition process used to deposit the second layer. This means that it is simpler to carry out both processes in the same deposition chamber. For example, it is simpler to carry out two plasma enhanced atomic layer deposition processes in the same chamber than to provide a deposition chamber in which the protective layer can be deposited in a plasma enhanced atomic layer deposition process and the second layer can be deposited in a different pulsed plasma deposition process, such as pulsed chemical vapour deposition. For this reason, and due to the benefits of plasma enhanced atomic layer deposition discussed above, it is preferable for the protective layer and the second layer to both be deposited in a plasma enhanced atomic layer deposition process.

Nevertheless, in preferable embodiments of the first aspect of the invention, the protective layer and the second layer are formed from different materials. Therefore, even in embodiments where the same type of deposition process is used to deposit both layers, the deposition processes themselves will differ to suit the material being deposited to form each layer.

In order to reduce or eliminate the presence of potentially damaging radicals (such as oxidizing radicals in the case of a graphene 2-dimensional layer) in the deposition chamber or chambers used to deposit the protective layer and the second layer, the method of the first aspect of the invention preferably comprises one or more conditioning steps.

To this end, the step of depositing a protective layer is preferably carried out in a first deposition chamber and the method further comprises, prior to the step of depositing a protective layer, depositing a protective layer onto a second substrate in the first deposition chamber, removing the second substrate from the first deposition chamber, and providing the first substrate in the first deposition chamber.

In this conditioning step a protective layer, which has a similar composition as the protective layer deposited on the first substrate, is deposited on a second substrate. In doing so, the levels of any non-desired species such as oxygen which might have been present in the deposition chamber, either in the plasma used in the pulsed plasma deposition process or on the deposition chamber walls, are strongly reduced. This improves the subsequent deposition of the protective layer by reducing the potential for damage to the 2-dimensional layer of the first substrate and for defects in the layer of deposited material.

This first conditioning step could also comprise carrying out a step of depositing a protective layer in the first deposition chamber absent a substrate in said chamber, so as to condition the first chamber.

For similar reasons, a chamber conditioning step could be carried out prior to the step of depositing a second layer.

The step of depositing a second layer may be carried out in a second deposition chamber with the method further comprising, prior to the step of depositing a second layer, depositing a third layer onto a third substrate in the second deposition chamber, removing the second substrate from the second deposition chamber, and providing the first substrate in the second deposition chamber. However, the first deposition chamber is preferably the second deposition chamber, which is to say that both the step of depositing a protective layer and the step of depositing a second layer, along with one or both conditioning steps, are preferably carried out in the same deposition chamber.

This second conditioning step could also comprise carrying out a step of depositing a protective layer in the first deposition chamber absent a substrate in said chamber, so as to condition the first chamber.

According to a second aspect of the invention, a method for deposition of materials onto a 2-dimensional layer of a first substrate is provided, the method comprising: depositing a protective layer directly onto the 2-dimensional layer in a radical enhanced atomic layer deposition process; and depositing a second layer onto the protective layer in a second deposition process.

The second aspect of the invention provides an alternative method of depositing materials onto a 2-dimensional layer without damaging the 2-dimensional layer and whilst ensuring the deposited materials are high quality, which is to say that defects in the layers of deposited materials are reduced.

As noted above, the surfaces of 2-dimensional materials such as graphene have a low density of nucleation sites and are also highly sensitive to damage, meaning that deposition processes involving extended exposure to reactive species are typically unsuitable and lead to excessive damage of the 2-dimensional layer. This problem is addressed by the second aspect of the invention by using a radical enhanced atomic layer deposition process.

A radical enhanced atomic layer deposition process is another style of pulsed plasma deposition method and is similar to a plasma enhanced atomic layer deposition process in that they are both cyclic deposition processes in which a precursor is first provided in each deposition cycle to deposit adsorbed species onto the surface of a substrate and then purged from the deposition chamber. However, in a radical enhanced atomic layer deposition process a flux of reactive species comprised substantially of radicals or a mixture of radicals and a non-ionized gas with few or no ionized species is used to provide the reactive species which react with the adsorbed species on the surface of the substrate rather than exposing the substrate to a plasma.

There are different ways of providing the gas of radicals, including by providing a plasma in a separate plasma chamber to the deposition chamber in which the substrate is provided and directing a stream of radicals towards this deposition chamber. Because the mean free path of ions in a plasma is significantly shorter than that of radicals, it is possible to design the plasma chamber in such a way that, at most, a negligible proportion of the ions in the plasma chamber reach the deposition chamber. The substrate is not, therefore, exposed to sufficient ions to damage its surface.

Nevertheless, radical enhanced atomic layer deposition process is preferably a hot wire assisted atomic layer deposition (HWALD) process. In a hot wire assisted atomic layer deposition process, the flux of radicals is provided by using a hot wire (such as a tungsten filament) to heat up a precursor gas to a temperature in the range of 1300° C. to 2000° C. to dissociate molecules in the precursor gas to form radicals with little or no ionization. These radicals then react with the adsorbed species on the surface of the substrate to leave a layer of deposited material.

The hot wire assisted atomic layer deposition process has the advantage that no ions are formed which might damage the surface of the substrate.

Many of the same considerations discussed in relation to the first aspect of the invention also apply to the second aspect of the invention. For example, the second aspect of the invention is especially advantageous when the 2-dimensional layer comprises graphene.

Likewise, the protective layer and/or the second layer preferably comprise a dielectric, and it is especially advantageous if one or both of the protective layer and the second layer comprise a high-k dielectric, which is to say a dielectric with a dielectric constant greater than or equal to 3.

It is also preferable for the protective layer to comprise a metal or semiconductor nitride; a metal or semiconductor carbide; or a metal or semiconductor carbonitride.

Although the protective layer is deposited in a radical enhanced deposition process, the second deposition process may comprise a plasma deposition process, which is advantageously a pulsed plasma deposition process such as plasma enhanced atomic layer deposition or pulsed chemical vapour deposition. Since the protective layer and the second layer are preferably formed from different materials, this may be preferable in cases where the second layer is formed from a material which is more readily deposited in a plasma deposition process than in other deposition processes.

The deposition chamber or chambers used in the second aspect of the invention may also be subject to the conditioning steps discussed above with reference to the first aspect of the invention.

### BRIEF DESCRIPTION OF THE FIGURES

The invention will now be described with reference to the accompanying figures, in which:

FIG. 1 shows an exemplary plasma processing tool suitable for use in embodiments of the present invention

FIGS. 2a, 2b, and 2c show comparisons of the Raman spectra for substrates before and after deposition of a second layer;

FIG. 3 shows a cross-sectional view of a device produced according to an embodiment of the invention;

FIG. 4 shows a cross-sectional view of a device produced according to another embodiment of the invention; and

FIG. 5 shows a perspective view of the device shown in FIG. 4.

### DETAILED DESCRIPTION

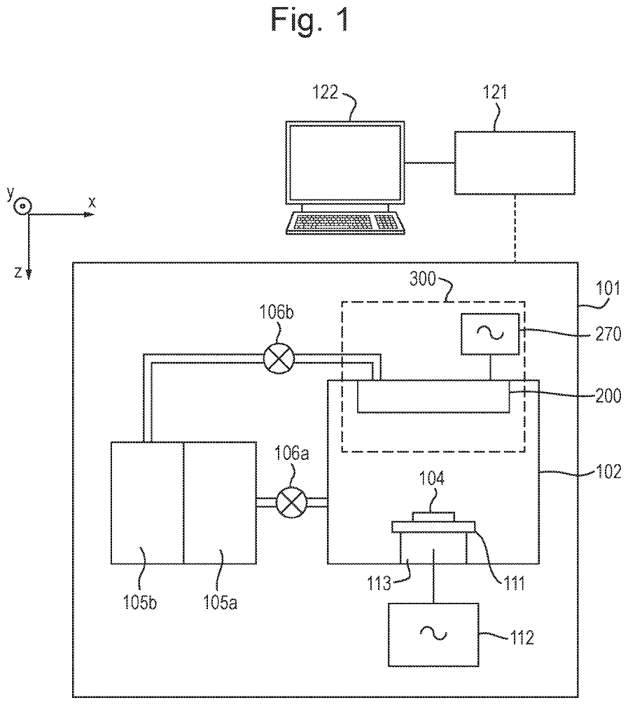

A schematic example of an exemplary plasma processing tool 101 for use in process according to embodiments of the invention is shown in FIG. 1.

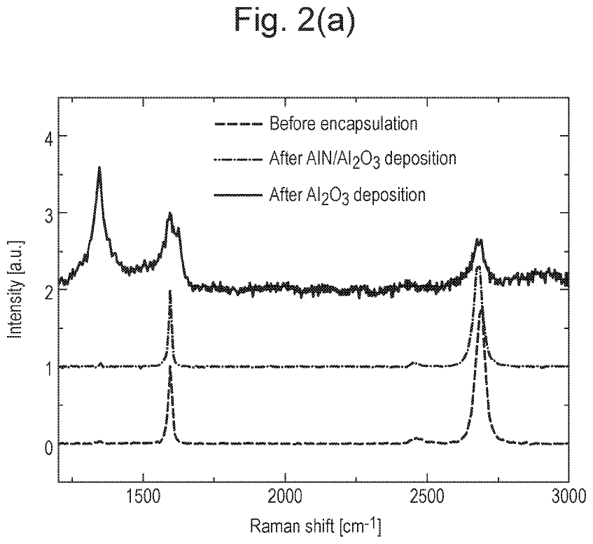

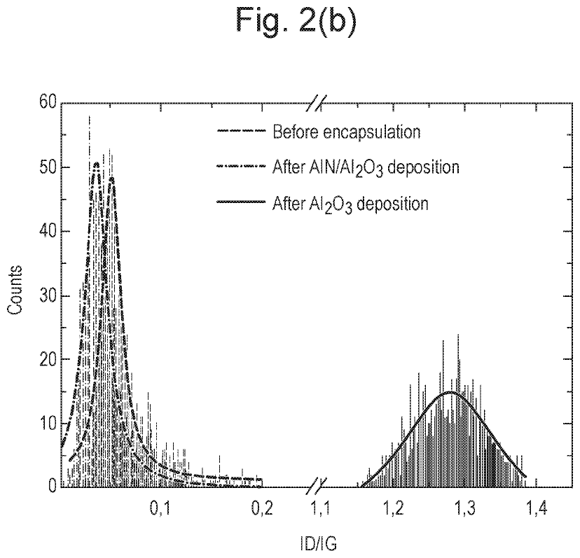

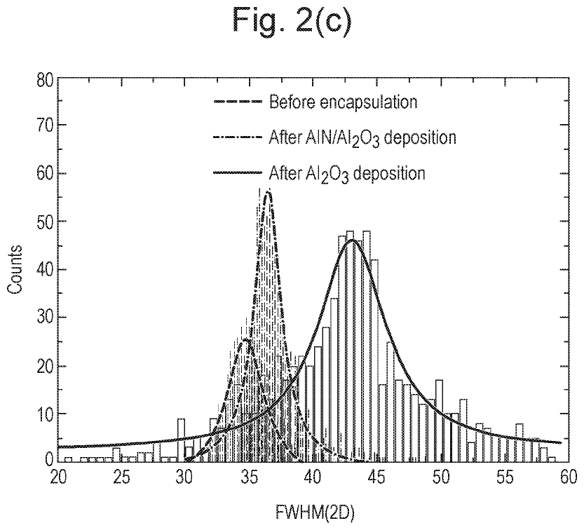

The plasma processing tool 101 includes a processing chamber 102 (which is also be referred to herein as a deposition chamber), which typically will contain a near vacuum, established by a vacuum pumping system (not shown). Inside the chamber 102 is a substrate table 111, on which a substrate 104 to be processed using the plasma processing tool 101 can be placed. The substrate table 111 is configured to be electrically connected to a signal generator 112, which is configured to electrically bias the substrate table 111 with an RF waveform, as described further below. Alternatively, such as in the exemplary embodiment described below with reference to FIG. 2, the table 111 may be grounded. The substrate table 111 may be supported by a lift 113, which can be controlled to raise or lower the substrate table 111 to a chosen height within the chamber 102. This may be used, for instance, to move the table 111 between a substrate loading position and a substrate processing position; the substrate processing position creating a smaller-volume inner chamber for rapid change of gas type in a cyclical process. The chamber 102 will also be provided with means (referred to herein as a cassette load lock) to load and unload a substrate 104 onto the table 111 without breaking vacuum (not shown).

An electrode array 200 is supported above the substrate table 103 inside the chamber 102. The electrode array 200 may include a panel (not labelled) that forms part or all of an upper wall of the plasma chamber 102. The electrode array 200 includes a series of alternately arranged ground electrodes (i.e. electrodes that are electrically grounded, not shown) and one or more live electrode(s) (not shown), which are electrically connected to a power source 270. The power source 270 is configured to electrically power the live electrodes so as to generate a voltage between the live and ground electrodes. In use, a precursor gas or a plasma for plasma generation can be fed to the electrode array 200, and the voltage between the live and ground electrodes breaks down the gas into a plasma. The electrode array 200 and the power source 270 are parts of the plasma generation apparatus 300.

The plasma processing tool 101 includes one or more gas sources such as those illustrated at 105a, 105b. The number and types of gas sources provided will depend on the nature of the plasma processing to be performed. For instance, if material is to be deposited (e.g. in atomic layer deposition processes), the gas source(s) will include one or more gases for the chemical reaction in question. In addition to depositing a protective layer and a second layer, embodiments of the present invention may comprise steps of depositing further layers of material or of etching layers of material. If the process involves etching material, the gas source(s) will include one or more etchant gases. Some processes such as the Bosch etching process involve both deposition and etching and so both types of gas will be available. Any of these reactant gases may be converted into a plasma by the apparatus 300. However in some cases additional gases may be provided specifically for plasma generation. Examples of suitable gases for plasma generation include noble gases (e.g. neon, Ne, and xenon, Xe), oxidising gases (e.g. oxygen, O₂, and nitrous oxide, N₂O), reducing gases (e.g. hydrogen, H₂) and nitrogen-bearing gases (e.g. molecular nitrogen, N₂, and ammonia, NH₃). One or more of the gas sources may also provide a purge gas, for limiting ingress of other gases and/or expelling a previous gaseous environment form the chamber 102. The purge gas could be, for example, a stable gas such as N₂ or argon (Ar).

As a specific example, typical cyclical plasma enhanced atomic layer deposition (ALD) processes have the following steps in each cycle:
A dose of precursor gas
A pump or purge step clearing the precursor gas from the chamber, leaving adsorbed species on the substrate surface
Exposure to gases excited by a plasma, which react with adsorbed species to create a solid thin film on the substrate
Optionally a pumping or purging step to clear plasma-excited gases from the chamber.

It is an advantage if the cycle time is as short as possible so as to minimise the plasma exposure time. Low pressure is used for the process, typically up to 1 mbar absolute pressure. Coupling power to the plasma must be reliable, even when most internal surfaces of the process chamber are coated at the same time as the substrate, and the deposited layer can be electrically conducting. Precursor gases used in many ALD processes are vapours which tend to condense easily unless all surfaces are heated, usually in the range 100 to 200 degrees C.

In the apparatus depicted in FIG. 1, the plasma generation gas source 105a is shown as delivering gas directly into the chamber 102 through a wall thereof, while gas source 105b is depicted as delivering a gas through the electrode array 200, but in practice either or both options may be employed for different gases. For example, the reactant gas(es) for the plasma processing step might be delivered through wall of the chamber (i.e. as per source 105a), whilst a delivery conduit through the electrode array 200 (i.e. as per source 105b) may be used to supply a purge gas between plasma processing steps, as will be discussed further below. There may also be multiple gas introduction points to the processing chamber for each gas source if desired. The supplies of precursor gas and gas for plasma generation from the sources 105a, 105b to the chamber 102 can be controlled using respective valves 106a, 106b. The valves are preferably tailored for injection of short gas pulses.

The plasma processing tool 101 is connected to a control unit 121, which may be commanded by a processor 122. The control unit 121 can control, for example, the power source 270, the signal generator 112, the valves 106a, 106b and the lift 113, in accordance with the processes to be performed on the substrate.

In a preferable embodiment of the invention, a protective layer and a second layer are deposited in plasma enhanced atomic layer deposition processes using the apparatus described above, with the substrate table grounded.

In a first (optional) stage of the process, the deposition chamber is conditioned by depositing an approximately 100 nm thick layer of AlN on a dummy wafer, using a TMA (trimethylaluminium) precursor and an N₂/Ar gas mixture plasma to passivate the chamber wall, so as to eliminate the presence of unwanted radicals (and oxygen radicals in particular) in the plasma. The plasma is then provided for 4 s with an RF power of 100 W, with a final purge step lasting 2 s. The pressure in the deposition chamber is 400 mtorr.

A protective layer of AlN is then deposited in a second stage of the process. The substrate used in this stage is prepared by transferring graphene on 6 inch (15 cm) Si wafers covered by 90 nm thermally grown SiO2.

In this stage, the N₂ and Ar gases are pulsed along with the TMA precursor. The plasma is then provided for 100 ms with an RF power of 25 W to 100 W. The pressure in the deposition chamber remains 400 mtorr.

A similar precursor and plasma gas mixture is used in stages 1 and 2, but with a lower plasma source RF power and shorter plasma time in the second stage. This mild plasma condition and low temperature allows for a thin layer of AlN to be grown without etching the underlying graphene. In doing so, the AlN protective layer effectively protects the graphene and creates functional groups, enabling the growth of an Al₂O₃ film in a subsequent step without damaging the graphene.

Stage 3 comprises an (optional) chamber conditioning stage prior to the deposition of Al₂O₃. Prior to this stage, the substrate processed in step 2 is transferred to the cassette load lock without breaking the vacuum. The chamber is then conditioned by depositing an approximately 70 nm thick layer of Al₂O₃ on a dummy wafer, using a TMA precursor and an O₂/Ar gas mixture plasma to passivate the chamber wall, so as to eliminate the presence of unwanted radicals in the plasma.

In this stage, the O₂ and Ar is pulsed along with the TMA. The plasma is then provided for 100 ms with an RF power of 100 W. The pressure in the deposition chamber is 400 mTorr for this stage.

In the final stage, the dummy substrate is removed and the substrate processed in step 2 transferred from the cassette load lock to the deposition chamber. Al₂O₃ is then deposited in the same process as stage 3. The protective layer allows for the substrate table temperature to be raised without risking damage to the device, and this higher temperature then allows for the quality and uniformity of the Al₂O₃ layer to be improved.

The AlN deposition and subsequent material deposition could also be performed in separate chambers using a vacuum transfer cluster tool.

In order to inspect the graphene's structural change caused by the encapsulation, Raman spectra of the graphene were recorded directly before and after encapsulation. FIGS. 2a to 2c show the Raman spectra for Gr/SiO₂/Si wafers before and after Al₂O₃ deposition with and without a protective AlN layer.

Generally, the Raman spectra of graphene show peaks at specific wavenumbers. The most prominent peaks are at around 1350 cm 1 for the D peak, 1582 cm 1 for the G peak, and 2700 cm⁻¹ for the 2D peak. The D peak provides information on the number of defects in the graphene lattice, with a larger D peak representing more defects in and damage to the graphene lattice. As shown in FIG. 2a, before dielectric deposition no D-peak is visible, indicating a good graphene quality. For the device with no protective AlN layer, a clear D peak becomes visible at around 1350 cm⁻¹ after encapsulation, demonstrating that the direct deposition of Al₂O₃ on graphene without a protective layer significantly damages the graphene. For the device protected by a protective AlN layer, the negligible D-peak demonstrates an efficient protection of the graphene layer.

The intensity ratio for the D peak and the G peak (I_{D}/I_{G}) is normally used to measure the level of defectsin the graphene. FIG. 2b shows the histogram of I_{D}/I_{G} obtained from a Raman map. The device encapsulated by Al₂O₃ without an AlN protective layer shows a significant increase in the I_{D}/I_{G} from 0.05 to 1.27. This is largely due to the induced damage to the graphene lattice by O₂ plasma exposure. In contrast, the sample protected with AlN shows a similar I_{D}/I_{G} of 0.035 compared to 0.05 for graphene with the difference attributable to a reduction of the noise level which is caused by changes in interference pattern.

Another useful measure is full-width-at-half-maximum (FWHM) of the 2D peak, which is representative of strain variations in graphene. A lower FWHM (2D) means a smaller strain variation and thus higher carrier mobilities in graphene. The histograms of FWHM (2D) acquired from the Raman map are shown in FIG. 2c. The sample without an AlN protective layer shows a significant increase of the FWHM (2D) from 34 cm⁻¹ to 43 cm⁻¹, while the AlN protected sample shows only a moderate increase from around 34 cm 1 to 36 cm⁻¹.

Some examples of devices produced according to embodiments of the invention will now be briefly discussed.

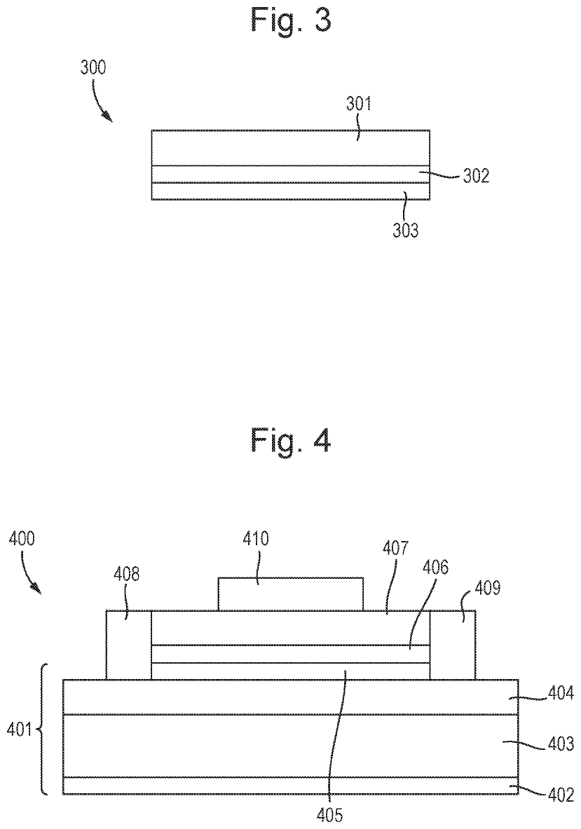

A first such example of a device 300 is depicted in FIG. 3, in which a protective layer 302 is provided directly on a substrate 301, with a further layer 303 provided on the protective layer 302. The upper layer of substrate 301 comprises a 2-dimensional layer, which is to say a layer of a 2-dimensional material, and substrate 301 may comprise one or more further layers.

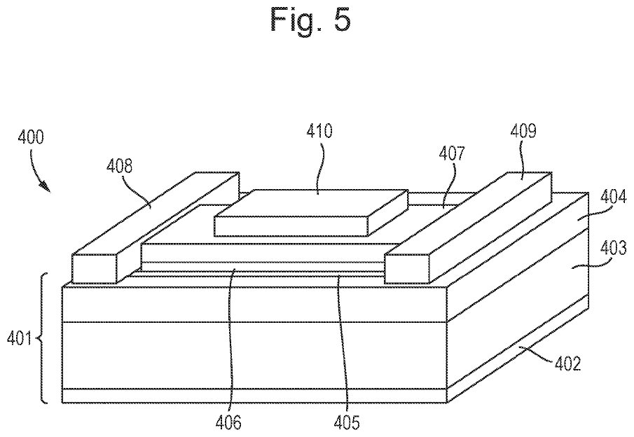

FIGS. 4 and 5 show a more complicated structure which is provided according to the same principles. In this case, a semiconductor device 400 is provided in which substrate 401 comprises a back-gate 402, an Si layer 403, an SiO₂ layer 404, and a graphene layer 405. As can be seen, the graphene layer does not extend across the full surface of the SiO₂ layer 404. In embodiments of the invention used to produce the device 400, the protective AlN layer 406 is deposited on substrate 401 first, followed by the Al₂O₃ layer 407, and finally the source 408, drain 409, and top-gate 410 layers. However, one or both of the source 408 and drain 409 layers could be provided before the AlN 406 and/or Al₂O₃ 407 layers.

1. A method for plasma deposition of materials onto a 2-dimensional layer of a first substrate, the method comprising:
depositing a protective layer directly onto the 2-dimensional layer in a pulsed plasma deposition process; and
depositing a second layer onto the protective layer in a second plasma deposition process.

2. A method of plasma deposition according to claim 1, wherein the 2-dimensional layer comprises graphene.

3. A method of plasma deposition according to claim 1, wherein the protective layer comprises a dielectric.

4. A method of plasma deposition according to claim 1, wherein the protective layer comprises a metal or semiconductor nitride; a metal or semiconductor carbide; or a metal or semiconductor carbonitride.

5. A method of plasma deposition according to claim 1, wherein the pulsed plasma deposition process comprises a plasma enhanced atomic layer deposition process or a pulsed plasma enhanced chemical vapour deposition process.

6. A method of plasma deposition according to claim 5, wherein the step of depositing a protective layer directly onto the substrate in a plasma enhanced atomic layer deposition process comprises using a low energy plasma.

7. A method of plasma deposition according to claim 1, wherein the second plasma deposition process comprises a pulsed plasma deposition process.

8. A method of plasma deposition according to claim 7, wherein the second plasma deposition process comprises a plasma enhanced atomic layer deposition process or a pulsed plasma enhanced chemical vapour deposition process.

9. A method of plasma deposition according to claim 7, wherein the second layer comprises a dielectric.

10. A method of plasma deposition according to claim 3, wherein the protective layer and/or the second layer each have a dielectric constant greater than 3.

11. A method of plasma deposition according to claim 1, wherein the protective layer and the second layer are formed from different materials.

12. A method of plasma deposition according to claim 1, wherein the step of depositing a protective layer is carried out in a first deposition chamber and the method further comprises, prior to the step of depositing a protective layer, depositing a protective layer onto a second substrate in the first deposition chamber, removing the second substrate from the first deposition chamber, and providing the first substrate in the first deposition chamber.

13. A method of plasma deposition according to claim 1, wherein the step of depositing a second layer is carried out in a second deposition chamber and the method further comprises, prior to the step of depositing a second layer, depositing a third layer onto a third substrate in the second deposition chamber, removing the second substrate from the second deposition chamber, and providing the first substrate in the second deposition chamber.

14. A method of plasma deposition according to claim 12, wherein the first deposition chamber is the second deposition chamber.

15. A method for deposition of materials onto a 2-dimensional layer of a first substrate, the method comprising:
depositing a protective layer directly onto the 2-dimensional layer in a radical enhanced atomic layer deposition process; and
depositing a second layer onto the protective layer in a second deposition process.

16. A method of deposition according to claim 15, wherein the radical enhanced atomic layer deposition process is a hot wire assisted atomic layer deposition process.

17. A method of plasma deposition according to claim 9, wherein the protective layer and/or the second layer each have a dielectric constant greater than 3.

18. A method of plasma deposition according to claim 2, wherein the protective layer and the second layer are formed from different materials.

19. A method of plasma deposition according to claim 2, wherein the protective layer comprises a dielectric.

20. A method of plasma deposition according to claim 13, wherein the first deposition chamber is the second deposition chamber.
